(19) United States
(12) Patent Application Publication
(10) Pub. No.: US 2009/0038832 A1
(43) Pub. Date: Feb. 12, 2009

(54) Device and method of forming electrical path with carbon nanotubes

(76) Inventors: Sterling Chaffins, Albany, OR (US); Kevin P. DeKam, Albany, OR (US); David P. Markel, Albany, OR (US); Karl S. Weibezahn, Albany, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/891,350

(22) Filed: Aug. 10, 2007

(51) Int. Cl. H05K 1/09; H05H 1/32

(52) U.S. Cl. 174/257; 427/540; 977/742

(57) ABSTRACT

Carbon nanotubes are dispersed in a curable polymer matrix to form a dispersion. When electrical energy is applied to the dispersion, the carbon nanotubes become oriented to form an electrical path. The polymer matrix is cured to fix the electrical path.

### BACKGROUND

A carbon nanotube is composed of a thin sheet or sheets of graphite in a rolled configuration to form a cylindrical shape. Carbon nanotubes are unique because they have a cylindrically diameter in the order of about a nanometer, but may have a length in the order of about a micrometer to about a millimeter (or more), thus providing the carbon nanotubes with a substantially large length to diameter ratio. The composition and shape of carbon nanotubes provide them with many unique and desirable properties. Because of these properties, carbon nanotubes are finding increasing application in various fields.

Carbon nanotubes have been heralded for their unique strength, elasticity, and thermal conductivity. In addition, carbon nanotubes also exhibit a variety of unique electrical properties. One such property is electrical conductivity. For example, carbon nanotubes can exhibit conductive behavior resembling a metal or a semi-conductor, depending on the shape and other physical characteristics of its cylinder. In addition, their small diameter to length ratio can constrain the movement of electrons. Thus, there are many features of carbon nanotubes that make them desirable for electronic applications, including the formation of electrical connections between various electrical elements.

### BRIEF DESCRIPTION OF THE DRAWINGS

Additional features and advantages of the disclosure will be apparent from the detailed description which follows, taken in conjunction with the accompanying drawings, which together illustrate, by way of example, features of the invention.

FIGS. 1 and 2 provide alternative schematic views embodiments of the present invention where electrodes are positioned along an x-y-axis; and

FIG. 3 provides a schematic view of an embodiment of the present invention where electrodes are positioned along an x-y-z-axis.

### DETAILED DESCRIPTION OF THE PREFERRED EMBODIMENT(S)

Reference will now be made to exemplary embodiments and specific language will be used herein to describe the same. It will nevertheless be understood that no limitation of the scope of the disclosure is thereby intended. Alterations and further modifications of the inventive features described herein, and additional applications of the principles of the disclosure as described herein, which would occur to one skilled in the relevant art and having possession of this disclosure, are to be considered within the scope of the disclosure. Further, before particular embodiments of the present disclosure are disclosed and described, it is to be understood that this disclosure is not limited to the particular process and materials disclosed herein as such may vary to some degree. It is also to be understood that the terminology used herein is used for the purpose of describing particular embodiments only and is not intended to be limiting, as the scope of the present disclosure will be defined only by the appended claims and equivalents thereof.

In describing and claiming the present disclosure, the following terminology will be used.

The singular forms “a,” “an,” and “the” include plural referents unless the context clearly dictates otherwise. Thus, for example, reference to “an electrical path” includes reference to one or more electrical paths.

As used herein, “aspect ratio” refers to the ratio of the longest dimension to the shortest dimension of a carbon nanotube. Therefore, an increase in aspect ratio would indicate that the longest dimension has increased over the shortest dimension. For example, a carbon nanotube having a 1 nm diameter and a length of about 1 μm has an aspect ratio of 1000:1. Further, an aspect ratio of 100:1 would be considered greater than an aspect ratio of 10:1. The dimensions are measured along edges or across a major axis to provide measurement of dimensions such as length, width, depth, and diameter. Thus, diagonal corner-to-corner measurements of dimension are not considered in the calculation of the aspect ratio. When referring to a plurality of nanostructures having a defined aspect ratio, what is meant is that all of the nanostructures of a composition as a whole have an average aspect ratio as defined.

“Carbon nanotubes” refers to carbon structures that can be as thin as a one-atom thick graphene sheet of graphite, or can be thicker than single wall carbon structures, and are often rolled up into a cylinder with the diameter on the order of about a nanometer. The shortest dimension (width) of a carbon nanotube is, by definition, in the nanometer range and is typically from about 0.1 nm to about 100 nm and most often from about 2 nm to about 50 nm. The longest dimension (length) can range from tens of nanometers to a macroscopic scale in the range of millimeters. However, typical lengths can range from about 20 nm to about 100 μm. Often, the aspect ratio of carbon nanotubes is at least 10,000, though this is not required. This being said, it is noted that physical dimensions of nanostructures can vary considerably.

As used herein, “conductive path” or “electrical path” refers to any mass of carbon nanotubes which exhibits electrically conductive properties. The mass of carbon nanotubes can be particles which are in physical contact or in close enough proximity to facilitate electrical conductivity. Typically, the electrical path includes carbon nanotubes that are oriented and/or concentrated in such a manner that they are more conductive than when a similar concentration of nanotubes is present in a random orientation, or prior to applying electrical energy to the carbon nanotubes to orient and/or concentrate them in an electrically useful configuration. Further, this term is intended to encompass conductive, semi-conductive, and the like, as distinguished from insulating materials. The conductive path can be in the form of an electronic trace or as part of more complicated circuitry, e.g., resistors, inductors, capacitors, etc.

Concentrations, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a size range of about 1 μm to about 200 μm should be interpreted to include not only the explicitly recited limits of 1 μm and about 200 μm, but also to include individual sizes such as 2 μm, 3 μm, 4 μm, and sub-ranges such as 10 μm to 50 μm, 20 μm to 100 μm, etc.

In accordance with this, AC dielectrophoresis or other similar methods can be used in a flow cell, drop cast, or laminate film configuration in which carbon nanotubes are deposited across an electrode gap. By using a curable polymer matrix, a laminate device or other similar device can be fabricated in which electrical connections can be made along an x-y-axis, a z-axis, or any combination of the two. The curable polymer matrix can be used to stabilize the environment around the electrical connections, and ultimately, can seal the device. In accordance with this recognition, embodiments of the present disclosure are drawn to various methods and devices. It is noted that various details are provided herein which are applicable to each of the method, device, product by process, or systems described herein. Thus, discussion of one specific embodiment is related to and provides support for this discussion in the context of the other related embodiments.

In accordance with embodiments of the present disclosure, a method of forming an electrical path can comprise dispersing carbon nanotubes in a curable polymer matrix to form a dispersion; applying electrical energy to the dispersion, wherein the carbon nanotubes become oriented and/or concentrated to form the electrical path; and curing the polymer matrix to fix the electrical path. In one embodiment, a device can be prepared in accordance with the methods described herein.

The polymer matrix can be UV curable and the step of curing the polymer matrix comprises introducing UV energy to the polymer matrix. In another embodiment, the polymer matrix can be thermally curable and the step of curing the polymer matrix comprises introducing thermal energy to the polymer matrix. Other curing methods known to those skilled in the art can also be used.

In one embodiment, dispersing the carbon nanotubes in the curable polymer matrix can include a step of homogenizing the carbon nanotubes and the polymer matrix to distribute the carbon nanotubes throughout the polymer matrix. Alternatively of additionally, dispersing the carbon nanotubes in the curable polymer matrix can include a step of using sonication to distribute the carbon nanotubes throughout the polymer matrix. Further, applying the electrical energy can include utilizing at least one electrode. In this embodiment, with respect to the electrode, the user or an automated system can apply a voltage to the at least one electrode to form the electrical path, wherein the electrode defines one end point of the electrical path.

A step of depositing the dispersion on a substrate in preparation for applying the electrical energy can be carried out, and in one embodiment, the step of depositing the dispersion on the substrate includes the step of depositing the dispersion in electrical communication with a plurality of electrodes, wherein a gap exists between the plurality of electrodes. Thus, the electrodes can be positioned along a planar x-y-axis with respect to one another, and the electrical energy can be applied to the electrodes forms the electrical path across a gap between adjacent electrodes along the x-y-axis. Alternatively or additionally, the electrode can be positioned along a z-axis with respect to the x-y-axis, and the electrical energy can be applied to the electrodes to form the electrical path along the z-axis. In this manner, electrical paths or circuitry can be formed not only the x-y-axis, but also along the z-axis or in three-dimensions along the x-y-z-axis. Stacking of cured polymer matrix devices with carbon nanotube traces or circuitry contained therein can be used to generate such a device.

An additional step can include applying an electrical current to the electrical path after the electrical path is formed. For example, this can occur after the polymer matrix is cured. Further, the step of applying electrical current can be used to removes metallic carbon nanotubes from the electrical path.

In accordance with another embodiment, a device can be prepared which comprises a cured polymer matrix; and carbon nanotubes oriented in a non-random configuration to form an electrical path capable of communicating an electrical signal, wherein the cured polymer matrix substantially holds the carbon nanotubes in position to fix the electrical path.

In one specific embodiment, the device can further include a second cured polymer matrix, and a second group of carbon nanotubes oriented in a non-random configuration to form a second electrical path capable of communicating an electrical signal, wherein the second cured polymer matrix substantially holds the second group of carbon nanotubes in position to fix the second electrical path. In this embodiment, the cured polymer matrix and the second cured polymer matrix can be positioned with respect to one another such that the electrical path and the second electrical path are in electrical communication with one another. It is noted that this describes a bilayer configuration, but the present disclosure is not limited to a bilayer. In one embodiment, multiple layers can be deposited on one another in a “layer by layer” assembly scheme.

The cured polymer matrix can include carbon nanotubes that are present outside of the electrical path, but which are not oriented to conduct the electrical signal or which are not at a concentration above a percolation threshold. Thus, it is often electrical energy that can be used to generate traces or circuitry prior to curing of the polymer matrix, and it is the cured polymer matrix that can be used to fix the carbon nanotubes in such a manner to maintain traces or electrical circuitry within the polymer matrix. Again, the cured polymer matrix can be a UV cured polymer matrix, or alternatively, a thermally cured polymer matrix. Other means of curing polymers can also be employed as would be apparent to one skilled in the art after considering the present disclosure, e.g., chemical (cationic/anionic), e-beam, etc.

It is noted that there are various configurations that can be designed in accordance with embodiments of the present disclosure. For example, the device can include electrodes on opposing ends of the electrical path and operable within the electrical path to communicate an electrical signal. The electrodes can be secured at opposing ends of the electrical path by the cured polymer matrix. In one embodiment, the device can include a plurality of electrical paths, at least one electrical path being present along a planar x-y-axis. Alternatively or additionally, the electrical path can be present along a z-axis with respect to the planar x-y-axis. In any of these embodiments, the electrical path can have an electrical resistance from 100 ohm and 1 Gohm in one embodiment.

There are several advantages of the present disclosure, some of which include: 1) the ability to use dielectrophoresis with carbon nanotubes in a laminate configuration to help with manufacturing; 2) the ability to stabilize a matrix for flexibility in forming electrical connections; 3) the ability to reduce or prevent sagging of carbon nanotubes over an electrode gap; 4) the ability to use dielectrophoresis in three dimensions by allowing for the formation of a laminate device, making the z-axis accessible for use; and 5) the ability to tune resistance and/or other connectivity properties.

In further detail with respect to these advantages, it is noted that electrode alignment is not critical. Electrical connections can be made over larger gaps than with many other systems, e.g., electrical connections of at least 10 μm, at least 30 μm, at least 50 μm, or even 100 μm or greater. As long as the resistance is monitored during deposition, the electrical connection can be made over long distances and in any spatial dimension. Additionally, not only does the curable polymer matrix act as a support for the electrical connection structure, it also keeps the carbon nanotubes from flexing and interacting with other electrical components. The matrix also can serve to laminate and seal the top and bottom electrodes when in a vertical configuration. Vertical connections can be easily made and tuned over a wide resistance range. If needed, the connections can also be used as semiconductors by burning away the metallic nanotubes after deposition. Additionally, if opaque substrates are used in the device that prevent UV light from being used, a thermal curing system can also be used using common curing mechanisms such as free radical (e.g., thiolene), anionic, cationic, or other polymer curing mechanism.

Regarding the tuning of connections, the methods describe herein can include a tuning step prior to curing the polymer matrix. The tuning step can include selecting a desired electrical resistance for the electrical path; applying electrical energy to the carbon nanotubes; measuring electrical resistance of the electrical path; and removing the electrical energy when the desired electrical resistance is measured. After deposition or orientation, further tuning can be achieved by an electrical breakdown method. In this case, resistance will increase as metallic CNTs are selectively destroyed. In one embodiment, the tuning step can include selecting the desired electrical resistance at from 100 ohm and 1 Gohm, for example. Thus, a device includes (during manufacture) a unique antifuse material for forming specialty devices, such as field programmable gate arrays or resistors in passive matrix codeword addressing schemes in displays. For comparison Si antifuses cannot attain intermediate resistances, as this material is either in an “on” or “off” orientation. In the case of dielectrophoresis with carbon nanotubes, resistances from >1 Gohm to <100 ohm are accessible. Furthermore, since the deposition involves a mixture of conducting and semiconducting nanotubes, a pure semiconducting connection can be made by “burning” away metallic tubes using current after deposition. Additionally, once the nanotubes are in an acceptable configuration for a desired application, the polymer matrix can be cured to fix the device.

There are some design issues that can be considered when forming devices or carrying out methods in accordance with embodiments of the present disclosure. For example, when electrodes are mobile (i.e. not attached on the same plane) resistance between the electrodes can decrease upon curing when the polymer matrix shrinks. The opposite is the case with static electrodes, such as in a planar configuration. In planar configurations, resistance tends to increase because electrodes remain stationary as the polymer matrix shrinks upon curing. Also, since a flow cell is not required for use, there are only a certain amount of nanotubes accessible to make electrical connections. For low resistance connections or a high number of connections per unit volume, it can be beneficial to increase the concentration of the nanotubes within the polymer matrix.

Suitable materials that can be used in accordance with embodiments of the present disclosure include UV curable polymers, such as CDG070 from Norcote, or alternatively, thermally curable polymers such free radical polymers which utilize thermal initiators, e.g., azo initiators (AIBN) or peroxide initiators (benzoyl peroxide). Further, suitable carbon nanotubes that can be use include carbon nanotubes from Carbon Solutions. It is also noted that dispersing agents, such as surfactants, can be used to aid in generating appropriate dispersions.

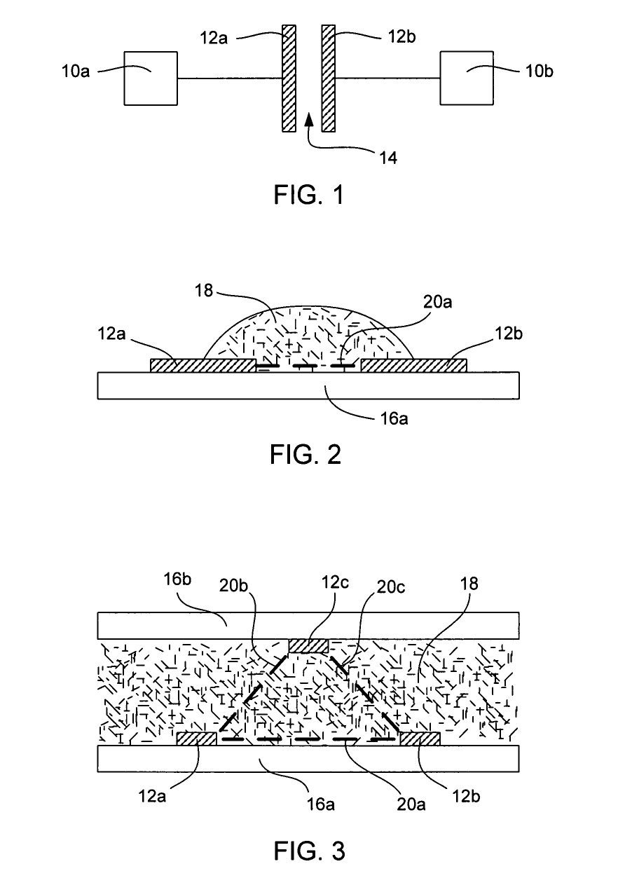

Turning to the FIGS., a few exemplary embodiments are provided which illustrate non-limiting aspects of the invention. FIGS. 1 and 2 illustrate embodiments wherein electrodes 12a, 12b are positioned on a substrate 16a for generating an electrical path 20a across a gap 14 along a planar or x-y-axis. In the embodiment shown, contact pads 10 are used to provide electrical current to the electrodes, and a nanotube dispersion 18 is present at least within the gap, which provides the fluid which forms the electrical path upon application of electrical energy. Once the path is formed, the fluid can be cured, as described herein.

Similarly, FIG. 3 illustrates embodiments wherein electrodes 12a, 12b, 12c are positioned on two different substrates 16a, 16b for generating various electrical paths 20a, 20b, 20c across various gaps. This embodiment provides electrical paths oriented along any of several x-y-z-axes. For example, path 20a can be generated using electrodes 12a and 12b; path 20b can be generated using electrodes 12a and 12c; and path 20c can be generated using electrodes 12b and 12c. Combinations of paths can also be generated. Again, a nanotube dispersion 18 is present between the electrodes, which provides the fluid which forms the electrical path upon application of electrical energy. Once formed, the fluid can be cured to fix the electrical paths, in accordance with embodiments of the present invention. It is noted that any of these embodiments can be used by stacking multiple layers to form laminates in three dimensions or otherwise. In some embodiments, one or more substrate(s) can be removed to provide the ability to stack layers, or alternatively, single layer devices can be formed, as would be appreciated by one skilled in the art after considering the present disclosure.

### EXAMPLES

### Example 1

### Preparation of Carbon Nanotube Curable Polymer Matrix Dispersion

Carbon nanotubes (from Carbon Nanotechnologies, Inc) were dispersed in a UV curable formulation (CDG070 from Norcote) using homogination and sonication. The UV curable matrix was of a low viscosity. For dispersion, perfect separation of nanotube bundles is not needed; however, the dispersion was carried out such that large bundles were not visible directly after sonication. A grey solution resulted. It is noted that higher viscosity fluids create more drag and lower the effective dielectrophoretic force on the carbon nanotubes, but can be used as long as an effective dispersion can be generated.

### Example 2

### Preparation of Planar Electrical Device

In a planar electrode configuration, the dispersion of Example 1 was deposited onto an electrode gap. It is noted that the UV light is kept from the system before curing to keep viscosity low. A dielectrophoretic electrical signal (8V, 1 MHz) was then applied and carbon nanotubes were deposited. The resistance across the electrode gap was monitored until a desired resistance was attained. In this example, the desired resistance was 100 Ohm though resistances from 100 OHM to 1 GOhm could have been obtained using this composition. The sample was then UV cured to lock the electrical connection in place. Upon curing, it was noticed that the resistance increased to some degree. This is likely due to the shrinkage of the polymer upon curing. In a planar configuration, shrinkage has the potential of pulling the electrical connections away from the electrode, and thus, care to ensure that this is taken into account when forming devices in accordance with embodiments of the present disclosure may be prudent, depending on the parameters of the specific application.

### Example 3

### Preparation of Three-Dimensional Electrical Device

In a vertical configuration (z-axis), a top electrode is laminated over a bottom electrode with the carbon nanotube dispersion of Example 1 in between. Corners can be frozen in place by spot UV curing outside of the working area before working with the sample. After the device was spot cured in non-active corners, a dielectrophoretic electrical signal was applied until a desired resistance was reached. In this example, the desired resistance was 100 Ohm though resistances from 100 OHM to 1 GOhm could have been obtained using this composition. The entire device was then UV cured. Upon curing, resistance decreased which was indicative of shrinkage of mobile electrodes (during lamination, the shrinkage of the UV resin brings both electrodes closer together and tightens the intermolecular carbon nanotube interaction). Thus, care to ensure that this is taken into account when forming devices in accordance with embodiments of the present disclosure may be prudent, depending on the parameters of the specific application.

While the above examples are illustrative of the principles of the present disclosure in one or more particular applications, it will be apparent to those of ordinary skill in the art that numerous modifications in form, usage and details of implementation can be made without the exercise of inventive faculty, and without departing from the principles and concepts of the disclosure. Accordingly, it is not intended that the disclosure be limited, except as by the claims set forth below.

What is claimed is:

1. A method of forming an electrical path, comprising:
dispersing carbon nanotubes in a curable polymer matrix to form a dispersion;
applying electrical energy to the dispersion, wherein the carbon nanotubes become oriented to form the electrical path; and
curing the polymer matrix to fix the electrical path.

2. The method of claim 1, wherein the polymer matrix is UV curable and the step of curing the polymer matrix comprises introducing UV energy to the polymer matrix.

3. The method of claim 1, wherein the polymer matrix is thermally curable and the step of curing the polymer matrix comprises introducing thermal energy to the polymer matrix.

4. The method of claim 1, wherein the step of dispersing the carbon nanotubes in the curable polymer matrix includes a step of homogenizing or sonicating the carbon nanotubes and the polymer matrix to distribute the carbon nanotubes throughout the polymer matrix.

5. The method of claim 1, wherein the step of applying the electrical energy includes a step of applying a voltage to a at least one electrode to form the electrical path, wherein the electrode defines one end point of the electrical path.

6. The method of claim 1, further comprising the step of depositing the dispersion on at least one substrate in preparation for applying the electrical energy, wherein the dispersion is in electrical communication with a plurality of electrodes when on the substrate, and wherein a gap exists between the plurality of electrodes.

7. The method of claim 6, wherein the electrodes are positioned along a planar x-y-axis with respect to one another, and wherein the electrical energy is applied to the electrodes to form the electrical path across a gap between adjacent electrodes along the x-y-axis.

8. The method of claim 6, wherein at least one electrode is positioned along a z-axis with respect to the x-y-axis, and wherein the electrical energy is applied to the electrodes to form the electrical path along the z-axis.

9. The method of claim 1, further comprising the step of applying an electrical current to the electrical path after the electrical path is formed.

10. The method of claim 9, wherein the step of applying the electrical current occurs after the polymer matrix is cured.

11. The method of claim 9, wherein the step of applying the electrical current removes metallic carbon nanotubes from the electrical path.

12. The method of claim 1, further comprising a tuning step prior to curing the polymer matrix, the tuning step comprising:
selecting a desired electrical resistance for the electrical path;
applying electrical energy to the carbon nanotubes;
measuring electrical resistance of the electrical path; and
removing the electrical energy when the desired electrical resistance is measured, wherein the desired electrical resistance is from 100 ohm and 1 Gohm.

13. The method of claim 1, further comprising a tuning step which includes selective destruction of metallic CNTs present after forming the electrical path.

14. A device prepared in accordance with claim 1.

15. A device, comprising:
a cured polymer matrix; and
carbon nanotubes oriented in a configuration to form an electrical path capable of communicating an electrical signal, wherein the cured polymer matrix substantially holds the carbon nanotubes in position to fix the electrical path.

16. The device of claim 15, wherein the cured polymer matrix includes carbon nanotubes that are present outside of the electrical path, but which are not oriented or concentrated above a percolation threshold to conduct the electrical signal.

17. The device of claim 15, further comprising electrodes on opposing ends of the electrical path and operable with the electrical path to communicate an electrical signal, wherein at least one electrical path is present along a planar x-y-axis or along a z-axis with respect to the planar x-y-axis.

18. The device of claim 15, wherein the electrical path is free of metallic carbon nanotubes by the introduction of an appropriate electrical current to the electrical path to remove the metallic carbon nanotubes along the electrical path, and wherein the electrical path has an electrical resistance from 100 ohm and 1 Gohm.

19. The device of claim 15, wherein the device further includes:
a second cured polymer matrix, and
a second group of carbon nanotubes oriented in a configuration to form a second electrical path capable of communicating an electrical signal, wherein the second cured polymer matrix substantially holds the second group of carbon nanotubes in position to fix the second electrical path, wherein the cured polymer matrix and the second cured polymer matrix are positioned with respect to one another such that the electrical path and the second electrical path are in electrical communication with one another.

20. The device of claim 19, wherein the device includes three or more cured polymer matrix layers with electrical paths contained therein.
